(19) United States
(12) Patent Application Publication
(10) Pub. No.: US 2026/0026284 A1
(43) Pub. Date: Jan. 22, 2026

(54) SUBSTRATE PROCESSING APPARATUS AND METHOD OF PROCESSING SUBSTRATE

(71) Applicant: Samsung Display Co., Ltd., Yongin-Si (KR)

(72) Inventor: SUNGMIN HUCH, Yongin-si (KR)

(21) Appl. No.: 19/060,795

(22) Filed: Feb. 24, 2025

(30) Foreign Application Priority Data
Jul. 16, 2024 (KR) 10-2024-0093579

(51) Int. Cl. H01L 21/67; B08B 5/02; H01L 21/02; H01L 21/677

(52) U.S. Cl. CPC H01L 21/67028; B08B 5/023; H01L 21/02057; H01L 21/67703

(57) ABSTRACT

A substrate processing apparatus is disclosed that includes a first chamber having a first internal pressure, a second chamber connected to the first chamber and having a second internal pressure greater than the first internal pressure, a transfer mechanism located in the second chamber and configured to transfer a substrate, and a blower located in the second chamber and configured to blow air to the substrate.

### CROSS-REFERENCE TO RELATED APPLICATION(S)

The present application claims priority to and the benefit of Korean Patent Application No. 10-2024-0093579 filed on Jul. 16, 2024 in the Korean Intellectual Property Office (KIPO), the entire disclosure of which is incorporated herein by reference.

### BACKGROUND

### 1. Field

Embodiments relate to a substrate processing apparatus. More particularly, embodiments relate to a substrate processing apparatus and a method of processing a substrate.

### 2. Description of the Related Art

With the development of information technology, the importance of display devices, which are the medium of connection between users and information, is being highlighted. As a result, the use of display devices such as liquid crystal display devices (“LCD”s), organic light-emitting display devices (“OLED”s), and plasma display devices (“PDP”s) is increasing.

The display device is manufactured by forming various layers on a substrate. Some processes are carried out under atmospheric conditions, while others are carried out in a reduced-pressure chamber (i.e., under a vacuum atmosphere). Due to pressure fluctuations during various processes, contamination by floating particles may occur on the substrate.

### SUMMARY

This disclosure provides a substrate processing apparatus with improved yield.

This disclosure provides a method of processing a substrate with improved yield.

A substrate processing device according to an embodiment includes: a first chamber having a first internal pressure, a second chamber connected to the first chamber and having a second internal pressure greater than the first internal pressure, a transfer mechanism located in the second chamber and configured to move a substrate in a processing direction, and a blower located in the second chamber and configured to blow air to the substrate.

In an embodiment, in operation the air may be blown obliquely in a second and third direction in which the second direction is opposite to the processing direction.

In an embodiment, in operation the air may be blown at an angle of about 30 degrees or more and about 50 degrees or less with a virtual normal line of the substrate.

In an embodiment, an air blowing pressure may be about 0.2 MPa or more and about 0.4 MPa or less.

In an embodiment, in operation a downflow may be formed in the second chamber.

In an embodiment, a plurality of holes may be defined in a bottom surface of the second chamber, and in operation a foreign material may be removed from the substrate by the air, passes through the plurality of holes, and is isolated from an internal space of the second chamber.

In an embodiment, the air may be clean-dry-air (“CDA”).

In an embodiment, the substrate processing device may further include a third chamber connected to the second chamber and in which a foreign material detector is located inside.

In an embodiment, the foreign material detector may be a plurality of foreign material detectors.

In an embodiment, the first chamber may be a chemical vapor deposition (“CVD”) chamber.

A method of processing a substrate according to an embodiment includes: transferring a substrate from a first chamber having a first internal pressure into a second chamber having a second internal pressure greater than the first internal pressure, moving the substrate in a processing direction in the second chamber, and removing a foreign material from the substrate by blowing air on the substrate.

In an embodiment, the air may be blown obliquely in a second and third direction in which the second direction is opposite to the processing direction.

In an embodiment, the air may be blown at an angle of about 30 degrees or more and about 50 degrees or less with a virtual normal line of the substrate.

In an embodiment, an air blowing pressure may be about 0.2 MPa or more and about 0.4 MPa or less.

In an embodiment, a downflow may be formed in the second chamber.

In an embodiment, a foreign material may be removed from the substrate by the air, may passe through a plurality of holes defined in a bottom surface of the second chamber, and may be isolated from an internal space of the second chamber.

In an embodiment, the air may be clean-dry-air (“CDA”).

In an embodiment, the method of processing a substrate may further include inspecting for a presence or absence of the foreign material remaining on the substrate, after removing the foreign material from the substrate by blowing the air on the substrate.

In an embodiment, a first signal may be generated when the substrate is carried out of the first chamber, the air may begin to be blown in response to the first signal, and the blowing of the air may be stopped after a selected time has elapsed.

In an embodiment, a chemical vapor deposition (“CVD”) process may be performed in the first chamber.

The substrate processing apparatus according to embodiments may include a blower disposed in a section where a first internal pressure changes to a second internal pressure. The blower may remove a foreign material from a substrate by blowing air. Accordingly, yield may be enhanced.

In addition, the substrate processing apparatus may blow the air obliquely to the substrate to maximize an effect of removing the foreign material.

In addition, the substrate processing apparatus may maximize the effect of removing foreign material by optimizing a blowing pressure of the air.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a view illustrating a substrate processing line according to an embodiment.

FIG. 2 is a view illustrating an embodiment of a substrate processing apparatus.

FIG. 3 is a view illustrating an embodiment of a second process chamber included in the substrate processing apparatus of FIG. 2.

FIG. 4 is a view illustrating an object, which is processed, located in the second process chamber of FIG. 3.

FIG. 5 is a cross-sectional view taken along line I-I′ of FIG. 4.

FIGS. 6, 7, and 8 are views illustrating the blower and other features included in the substrate processing apparatus of FIG. 2.

FIG. 9 is a block diagram of an embodiment of a method of processing a substrate.

FIGS. 10, 11, 12, and 13 are views illustrating a method of processing a substrate according to an embodiments.

### DETAILED DESCRIPTION OF THE EMBODIMENTS

Hereinafter, embodiments will be described in more detail with reference to the accompanying drawings. The same reference numerals are used for the same components in the drawings, and redundant descriptions of the same components will be omitted.

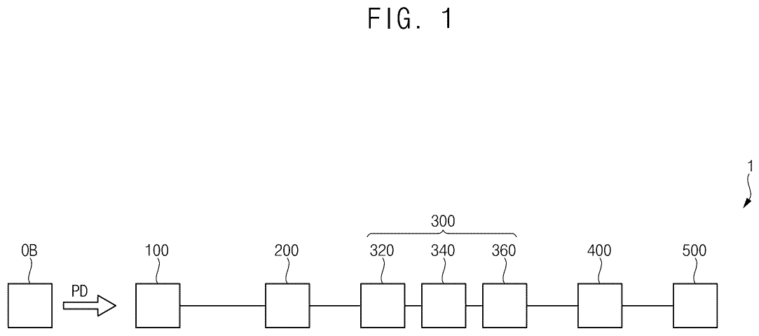

FIG. 1 is a view illustrating a substrate processing line according to an embodiment.

Referring to FIG. 1, a substrate processing line 1 may include processing systems that may be arranged in-line along a processing direction PD. The substrate processing line 1 may include a first processing system 100 which processes an object OB, a second processing system 200, a third processing system 300, a fourth processing system 400, and a fifth processing system 500. The processing direction PD may refer to a direction in which the object OB moves to perform a substrate processing process. Each of the processing systems may be referred to as a processing apparatus, a portion of a processing system may be referred to as a processing apparatus, or portions of two or more processing systems may be referred to as a processing apparatus.

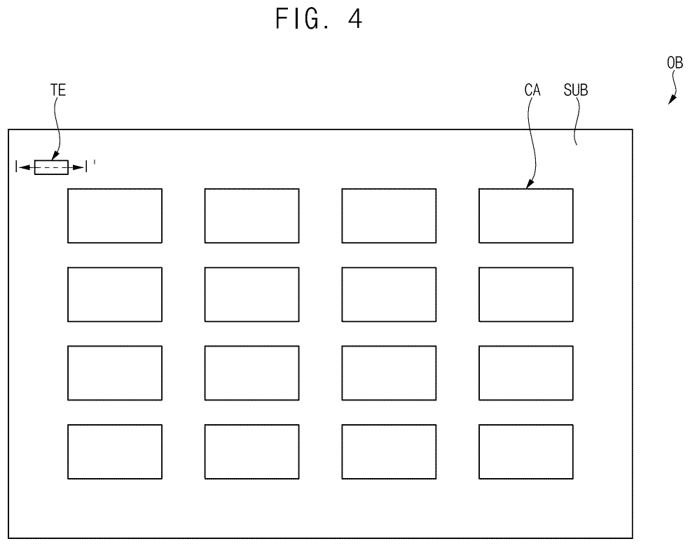

In an embodiment, the object OB may include a substrate. For example, the substrate may be a mother substrate on which a plurality of cells are defined. Detailed descriptions of the object OB will be described below with reference to FIG. 4 et seq. In the description that follows, the object OB is changed as it moves through the processing line 1. So, for example, when an apparatus adds a layer of material to the object OB, the layer of material may be referred to as included in the object OB.

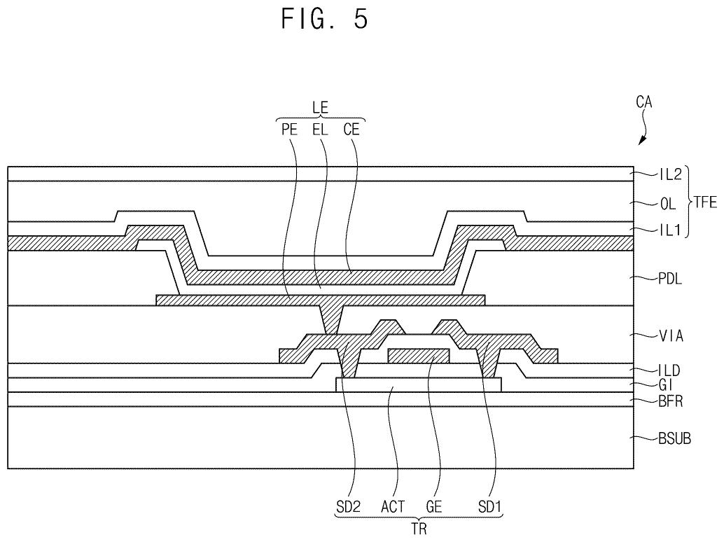

The first processing system 100 may perform a backplane process. The backplane process may refer to a process of forming a transistor (for example, a transistor TR of FIG. 5) included in the object OB. The transistor may be configured to turn on/off a power of each of a plurality of pixels included in the object OB and control brightness by supplying and adjusting current. Detailed descriptions of the backplane process will be described below with reference to FIG. 4 et seq.

The second processing system 200 may perform a deposition process. For example, the deposition process may refer to a process of forming an organic material layer (for example, an organic light-emitting layer EL of FIG. 5) included in the object OB. For example, the organic material layer may be configured to receive an electrical signal and emit color-light. Detailed descriptions of the deposition process will be described below with reference to FIG. 4 et seq.

The deposition chamber may be a plurality. Accordingly, the object OB may be transferred into the second processing system 200 may be transferred without delay into an empty chamber and the deposition process may be performed.

The second processing system 200 may have a high-vacuum (low-pressure) condition, and the first processing system 100 may have a pressure condition greater than the condition of the second processing system 200 (for example, room pressure). For example, the room pressure condition may be about 760 torr. For example, the vacuum condition may have a pressure condition that is about 50 torr or less.

A primary cleaning apparatus may be located between the first processing system 100 and the second processing system 200. The primary cleaning apparatus may remove a residual film, a foreign material, or the like on the object OB, before performing the deposition process in the second processing system 200. Accordingly, the yield may be enhanced.

The third processing system 300 may perform an encapsulation process. The encapsulation process may refer to a process of forming an encapsulation layer (for example, an encapsulation layer TFE of FIG. 5) that covers the organic layer included in the object OB. For example, the encapsulation layer may cover the organic material layer to protect moisture, oxygen, or the like, from penetrating into the organic material layer. Detailed descriptions of the encapsulation process will be described below with reference to FIG. 4 et seq.

The third processing system 300 may include a first deposition chamber 320, a printing chamber 340, and a second deposition chamber 360.

In the first deposition chamber 320, a first inorganic encapsulation layer may be formed on the substrate on which the organic material layer is formed. An organic encapsulation layer may be formed on the first inorganic encapsulation layer in the printing chamber 340. A second inorganic encapsulation layer may be formed on the organic encapsulation layer in the second deposition chamber 360. The inorganic encapsulation layer may prevent penetration of the moisture and the air. The organic encapsulation layer may flatten an upper surface of the inorganic encapsulation layer located below and ensure that the inorganic encapsulation layer to be located above is well seated when deposited.

The inorganic encapsulation layers may be formed through the deposition process in a high vacuum state. The organic encapsulation layer may be formed through a printing process in a high vacuum state.

The first deposition chamber 320, the printing chamber 340, and the second deposition chamber 360 may each be a plurality. Accordingly, the object OB may be transferred into the third processing system 300 without delay into an empty chamber and the process of forming the encapsulation layer may be performed.

In an embodiment, the third processing system 300 may include a first chamber having a first internal pressure.

More specifically, in an embodiment, the first chamber may be a chemical vapor deposition (“CVD”) chamber. However, the disclosure is not limited thereto. For example, the first chamber may perform plasma-enhanced CVD (“PECVD”), low-pressure CVD (“LPCVD”), metal-organic CVD (“MOCVD”), or the like.

A thin film may be any thin film that may be deposited by the chemical vapor deposition method. For example, the thin film may be a silicon-based thin film, however, the disclosure is not limited thereto. For example, the first chamber may deposit the thin film on the substrate through various deposition methods, and the thin film may include various materials such as inorganic materials, organic materials, metals, or the like.

An oven process may be performed in the fourth processing system 400. For example, the oven process may refer to a process of annealing the substrate. Accordingly, a device characteristic of the thin film transistor may be enhanced.

In an embodiment, the fourth processing system 400 may be connected to the third processing system 300. In other words, a second chamber included in the fourth processing system 400 may be connected to the first chamber. In an embodiment, a second internal pressure of the second chamber may be greater than the first internal pressure. For example, the second internal pressure may be room pressure (i.e., atmospheric pressure).

The fifth processing system 500 may be an inspection device. For example, the inspection device may include a foreign material inspection device using an optical system (i.e., an automatic optical inspection device). For example, the fifth processing system 500 may perform an inspection process. The inspection process may be a process of inspecting a location, length, presence of foreign material, or the like of a hole, a pattern, or the like during a manufacturing process of the display device.

In an embodiment, the fifth processing system 500 may be connected to the fourth processing system 400. In other words, the third chamber included in the fifth processing system 500 may be connected to the second chamber. In an embodiment, a foreign material detector may be located in the third chamber.

The foreign material detector may include a stage, an image acquisition part, a controller, an image processor, and an output part.

The substrate may be seated and supported on the stage. For example, the stage may have a rectangular plate shape. For example, the stage may move up, down, left, or right according to a first control signal from the controller. However, the disclosure is not limited thereto. For example, shape and operation of the stage may be changed in various ways.

The image acquisition part may acquire an image by shooting the substrate seated on the stage. The image acquisition part may radiate light on the substrate according to a second control signal from the controller and acquire the image from light reflected from the substrate. For example, light in an ultraviolet band (for example, light with a wavelength of about 280 nanometers (nm) to about 400 nanometers (nm)) may be radiated on the substrate. The light may cause the light-emitting device included in the substrate to emit light. The image of the substrate may be obtained from the light emitted from the light-emitting device.

The image acquisition part may also move up, down, left, or right according to a third control signal from the controller. For example, movement of the image acquisition part may be synchronized with movement of the stage. However, the disclosure is not limited thereto.

The controller may control the operation of the stage and the image acquisition part. For example, the controller may control the movement of the stage and the image acquisition part (for example, the movement up, down, left, or right). Accordingly, the substrate on the stage and the image acquisition part may be aligned. For another example, the controller may control the image acquisition part to emit the light. For another example, the controller may control the image acquisition part to acquire the image from light reflected from the substrate.

The controller may be hardware such as an electronic control unit (“ECU”), a microcontroller unit (“MCU”), software running on the hardware, or a combination thereof.

The image processor may process the acquired image data. For example, the image processor may obtain a luminance characteristic value of each pixel using a difference between each gray value constituting an image data and surrounding gray values.

The image processor may be implemented as an image processor that preprocesses the image data.

The image processor may determine whether there is a defect by comparing the acquired image data with a previously stored reference. For example, the image processor may determine whether the substrate is defective (for example, the presence or absence of the foreign material), or the like.

The output part may receive inspection data for the substrate from the image processor, and display a defect inspection result, an inspection status of the substrate, or the like, in real-time.

However, the disclosure is not limited thereto, and some components of the foreign material detector may be omitted or replaced. In addition, the foreign material detector may further include other components.

In an embodiment, the foreign material detector may be a plurality. Accordingly, the substrates transferred into the fifth processing system 500 may be transferred without delay into an empty foreign material inspection device and the inspection process may be performed.

However, the disclosure is no limited thereto. For example, the substrate processing line of FIG. 1 may further include various components or some of the components may be omitted/changed.

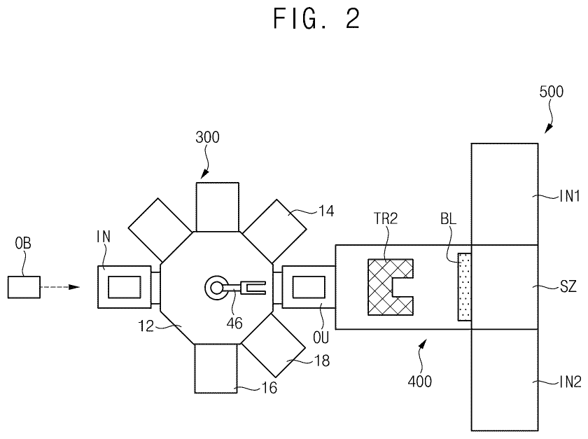

FIG. 2 is a view illustrating an embodiment of a substrate processing apparatus.

The third process system 300 of FIG. 2 schematically shows only the second deposition chamber 360 of FIG. 1.

Referring to FIGS. 1 and 2, the object OB may be sequentially moved to the third processing system 300, the fourth processing system 400, and the fifth processing system 500. As described above, the third processing system 300 may have the vacuum condition, and the fourth processing system 400 may have the room pressure condition.

In an embodiment, the blower BL may be located in a section where the vacuum condition is changed to the room pressure condition.

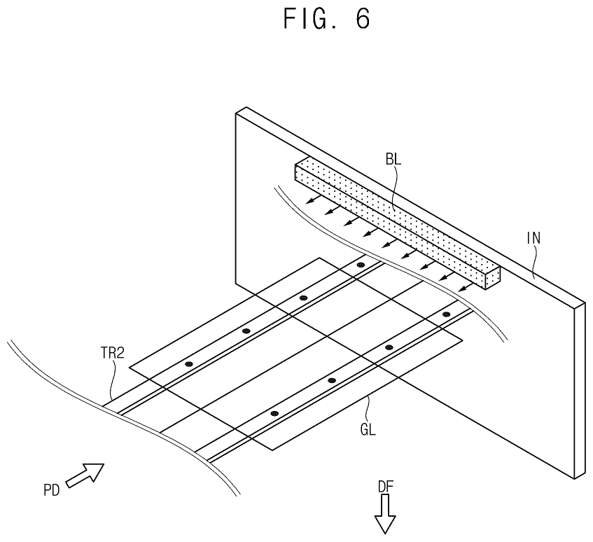

In the section where the vacuum condition is changed to the room pressure condition (i.e., a pressure change section), foreign material may be floating and may attach to the object OB. The blower BL may provide air to the object OB to blow away the foreign material. Detailed descriptions of the blower BL will be described below with reference to FIGS. 6, 7, and 8.

The object OB may be transferred into the third processing system 300 through an inlet IN. For example, the third processing system 300 may include a transfer chamber 12, a plurality of process chambers (for example, a first process chamber 14, a second process chamber 16, and a third process chamber 18), and a picker 46.

The picker 46 may be located in the transfer chamber 12. The picker 46 may transport the object OB into an empty process chamber.

The plurality of process chambers may be connected to each other with the transfer chamber 12 at the center and may be arranged in a cluster shape.

The plurality of process chambers may include the first process chamber 14, the second process chamber 16, and the third process chamber 18. For example, in case that the deposition process is in progress in the first process chamber 14, the object OB which enters the inlet IN may transfer to the empty second process chamber 16, and the deposition process may be performed.

The object OB may be carried outside of the third processing system 300 through an outlet OU. The picker 46 may transport the object OB which deposition has been completed to the outlet OU. For example, in case that the deposition process is completed first in the first process chamber 14, the object OB in the first process chamber 14 may be carried out through the outlet OU first.

However, the disclosure is not limited thereto. For example, the process chamber may be one, and location and shape of the picker 46 may be changed in various ways.

In an embodiment, a transfer mechanism TR2 may be located in the fourth processing system 400. The transfer mechanism TR2 may transfer the object OB.

As described above with reference to FIG. 1, in an embodiment, the foreign matter detector may be a plurality. For example, a first inspection device IN1 and a second inspection device IN2 may be located in the fifth processing system 500. A standby zone SZ may be located between the first inspection device IN1 and the second inspection device IN2.

In an embodiment, the blower BL may be located in the fourth processing system 400 adjacent to the fifth processing system 500. More specifically, the blower BL may be located in the fourth processing system 400 adjacent to the standby zone SZ of the fifth processing system 500. Accordingly, even if there is a plurality of foreign material detectors, only one blower BL may be installed.

In a case of a substrate processing line according to a comparative embodiment, the blower BL is not be included. In this case, a defect of the display device due to the foreign material may be detected in the fifth processing system 500.

However, in a case of the substrate processing line according to an embodiment, the blower BL may be located in a pressure fluctuation section. The blower BL may remove (by blowing) the foreign material attached to the object OB due to the pressure fluctuation. By preventing the occurrence of the defect by removing the foreign material, the yield may be enhanced compared to the substrate processing line according to the comparative embodiment.

Because a size of particles of the foreign material are small, the foreign material might not be detected in the fifth processing system 500. In this case, the defect such as a dark spot may occur by forming additional layers without detecting the foreign material.

However, in the case of the substrate processing line according to an embodiment, the blower BL may be included in the pressure fluctuation section, and the blower BL may remove (by blowing) the foreign material attached to the object OB, the defect due to the foreign material may be prevented. Accordingly, reliability of the display device may be enhanced.

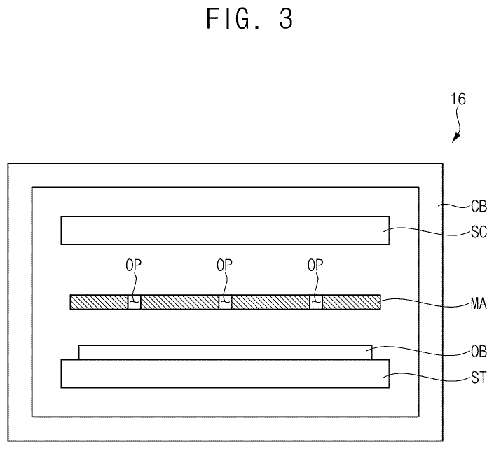

FIG. 3 is a view illustrating the second process chamber included in the substrate processing line of FIG. 1. FIG. 4 is a view illustrating a mask and an object located in the second process chamber of FIG. 3.

The first process chamber 14, the second process chamber 16, and the third process chamber 18 of FIG. 2 may have substantially a same or similar components. Therefore, hereinafter, following description will focus on the second process chamber 16.

Referring to FIGS. 3 and 4, the second process chamber 16 may include a chamber CB, a stage ST, a deposition source SC, and a mask MA.

The second process chamber 16 may be used in the manufacturing process of the display device. For example, the second process chamber 16 may be used in the deposition process to form the thin film on the object OB during the manufacturing process of the display device. The object OB may include the substrate. For example, the thin film may be formed on the substrate through the deposition process using the second process chamber 16.

The substrate may refer to a mother substrate including the display devices being manufactured. The substrate may further include at least one layer included in the display device. For example, the substrate may further include at least one layer included in the display device: an inorganic layer, an organic layer, or a metal layer.

The chamber CB may provide an internal space where the deposition process may be performed. For example, the chamber CB may be a reaction chamber including a reaction space therein. Various components that may be used in the deposition process may be located in the chamber CB. In case that performing the deposition process, a temperature inside the chamber CB may be relatively high. Accordingly, in case that performing the deposition process, heat may be applied to the components located in the chamber CB.

The stage ST may be located in the chamber CB. The stage ST may be parallel to a plane defined by a first direction and a second direction crossing the first direction. For example, the second direction may be perpendicular to the first direction. The substrate may be located on the stage ST. The stage ST may support and fix the substrate.

The stage ST may be movable in the chamber CB. For example, the stage ST may be able to move up and down in response to a loading time, unloading time, and preceding time, or the like of the deposition process time of the substrate. In an embodiment, the stage ST may heat and maintain the substrate at a selectable temperature. For example, the stage ST may include a heater or be connected to a heater. In addition, the stage ST may be connected to a power supply to serve as an electrode.

The deposition source SC may be located on the stage ST. The deposition source SC may be spaced apart from the stage ST in a third direction that crosses each of the first direction and the second direction. For example, the third direction may be perpendicular to each of the first direction and the second direction. The deposition source SC may supply deposition material in the chamber CB. In addition, the deposition source SC may be connected to the power supply and serve as an electrode.

In an embodiment, the deposition source SC may supply gas in the chamber CB. For example, the gas may include a reactive gas, a cleaning gas, or the like. For example, in case that a plasma is generated between the deposition source SC and the substrate in the chamber CB, the reactive gas may cause a chemical reaction with energy of the plasma and be deposited on the substrate, and the cleaning gas may cause a chemical reaction with the energy of the plasma and clean the components inside the chamber CB.

The mask MA may be located above the stage ST. For example, the mask MA may be located between the stage ST and the deposition source SC. The deposition material supplied from the deposition source SC may pass through the mask MA and be deposited on the substrate. The mask MA may have a pattern, and the deposition material may be deposited on the substrate in a pattern corresponding to the pattern of the mask. The mask MA may include metal. For example, the mask MA may include an alloy of nickel (“Ni”) and iron (“Fe”). For example, mask MA may include invar. However, the disclosure is not limited thereto.

The mask MA may be opposite the substrate. For example, the mask MA and the substrate may be parallel to the plane defined by the first direction and the second direction, respectively, and the mask MA may be adjacent to the substrate in the third direction.

In an embodiment, the mask MA may define a plurality of openings OP that are repeatedly arranged along the first and second directions. Each of the openings OP may penetrate the mask MA in a thickness direction (i.e., in the third direction). The thin film may be formed on the substrate in the pattern corresponding to a pattern of the openings OP. A width of the openings OP may be determined in response to the pattern to be deposited.

The substrate may define a plurality of cell areas CA on which the thin film is deposited. The pattern of the cell areas CA may correspond to the pattern of the openings OP. The cell areas CA may be repeatedly arranged along the first direction and the second direction. The cell areas CA may respectively correspond to the openings OP. Each of the cell areas CA may correspond to the display device being manufactured.

In FIG. 3, the mask MA is shown to be spaced apart from the substrate by a selectable distance, however, the disclosure is not limited thereto. For example, the mask MA may be located in contact with the substrate.

In addition, in FIG. 4, the openings OP and the cell areas CA are shown as having a rectangular shape in a plan view, however, the disclosure is not limited thereto. For example, the shapes of the openings OP and the cell areas CA may vary depending on the shape of the display device being manufactured.

The substrate processing line 1 of FIG. 1 may further include various components or some of the components may be omitted/changed.

In FIG. 3, the second process chamber 16 is described as being a horizontal deposition device, however, the second process chamber 16 may also be a vertical deposition device. In this case, the stage ST, mask MA, and deposition source SC included in the vertical deposition device may be arranged in a direction crossing the gravity direction (for example, a direction parallel to the third direction).

FIG. 4 is a top view of the object of FIG. 3. As shown in FIG. 4, the substrate SUB may define the cell areas CA that are repeatedly arranged along the first direction and the second direction.

In an embodiment, the substrate SUB may define the cell areas CA arranged in i rows and j columns (where i and j are natural numbers). For example, j-cell areas CA arranged along the first direction in each row and i-cell areas CA arranged along the second direction in each column may be defined in the substrate SUB. The substrate SUB may be defined i by j cell areas CA.

In an embodiment, an inspection area TE may be defined in the substrate SUB. For example, the inspection area TE may be located in an outer portion of the substrate SUB (for example, an outer portion of the cell areas CA). For example, the inspection area TE may have a size of about 10 millimeters (mm) by about 12 mm. However, the disclosure is not limited thereto.

FIG. 5 is a cross-sectional view taken along line I-I′ of FIG. 4.

The substrate SUB of FIG. 4 may form the plurality of display devices and be cut into individual display devices (cutting process). For example, FIG. 5 is a cross-sectional view schematically showing the display device manufactured using the substrate processing device 1 of FIG. 1.

Referring to FIGS. 4 and 5, in the cell areas CA and inspection areas TE, the display device may include a base substrate BSUB, a buffer layer BFR, a transistor TR, a gate insulating layer GI, an interlayer insulating layer ILD, a via insulating layer VIA, a light-emitting device LE, a pixel defining layer PDL, and an encapsulation layer TFE. For example, the cell areas CA may be an area for forming the individual display devices, and the inspection area TE may be an area for inspecting the presence or absence of abnormalities in the process. The inspection area TE may be omitted.

The transistor TR may include an active pattern ACT, a gate electrode GE, a first electrode SD1, and a second electrode SD2. The light-emitting device LE may include a lower electrode PE, a light-emitting layer EL, and an upper electrode CE. As described above, the transistor may be completed through the backplane process.

The base substrate BSUB may include a transparent material or an opaque material. For example, the base substrate BSUB may include plastic, glass, quartz, or the like. For example, the base substrate BSUB may include polyimide. These may be used alone or in combination with each other.

The buffer layer BFR may be disposed on the base substrate BSUB. The buffer layer BFR may prevent metal atoms, impurities, or the like from diffusing into the transistor TR. In addition, the buffer layer BFR may improve a flatness of a surface of the base substrate BSUB in case that the surface of the base substrate BSUB is not uniform. The buffer layer BFR may include an inorganic material such as silicon oxide (“SiOx”), silicon nitride (“SiNx”), silicon oxynitride (“SiOxNy”), or the like. These may be used alone or in combination with each other.

The active pattern ACT may be disposed on the buffer layer BFR. The active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (“IGZO”), indium tin zinc oxide (“ITZO”), or the like. These may be used alone or in combination with each other. The active pattern ACT may serve as a path through which current may pass below influence of a voltage applied to the gate electrode GE.

The gate insulating layer GI may be disposed on the active pattern ACT, and may cover the active pattern ACT. The gate insulating layer GI may include an inorganic material such as silicon oxide, silicon nitride, silicon oxynitride, or the like. These may be used alone or in combination with each other The gate insulating layer GI may insulate between the gate electrode GE and the active pattern ACT.

The gate electrode GE may be disposed on the gate insulating layer GI and the gate electrode GE may overlap the channel area of the active pattern ACT in a plan view. The gate electrode GE may include a metal, an alloy, a conductive metal nitride, a conductive metal oxide, a transparent conductive material, or the like. These may be used alone or in combination with each other. For example, the gate electrode GE may be controlled such that the current flows or does not flow in the active pattern ACT.

The interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

The first electrode SD1 and the second electrode SD2 may be disposed on the interlayer insulating layer ILD. The first electrode SD1 may be connected to the source area of the active pattern ACT through a first contact hole penetrating the gate insulating layer GI and the interlayer insulating layer ILD. In addition, the second electrode SD2 may be connected to the drain area of the active pattern ACT through a second contact hole penetrating the gate insulating layer GI and the interlayer insulating layer ILD. For example, each of the first electrode SD1 and the second electrode SD2 may include a metal, an alloy, a conductive metal nitride, a conductive metal oxide, a transparent conductive material, or the like. These may be used alone or in combination with each other.

Accordingly, the transistor TR including the active pattern ACT, the gate electrode GE, the first electrode SD1, and the second electrode SD2 may be disposed on the base substrate BSUB.

The via insulating layer VIA may be disposed on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, or the like. These may be used alone or in combination with each other.

The lower electrode PE may be disposed on the via insulating layer VIA. The lower electrode PE may be connected to the second electrode SD2 through a contact hole penetrating the via insulating layer VIA. The lower electrode PE may include a metal, an alloy, a conductive metal nitride, a conductive metal oxide, a transparent conductive material, or the like. These may be used alone or in combination with each other. For example, the lower electrode PE may operate as an anode.

The pixel defining layer PDL may be disposed on the via insulating layer VIA, and may cover at least a portion of the lower electrode PE. An opening exposing at least a portion of an upper surface of the lower electrode PE may be defined in the pixel defining layer PDL. The pixel defining layer PDL may include an inorganic material or an organic material. For example, the pixel defining layer PDL may include an organic material such as an epoxy resin, a siloxane resin, or the like. In another embodiment, the pixel defining layer PDL may include an inorganic material or an organic material including a light blocking material having a black color.

The light-emitting layer EL may be disposed on the lower electrode PE. The light-emitting layer EL may be disposed on the lower electrode PE exposed by the pixel defining layer PDL. The light-emitting layer EL may include an organic material. For example, the organic light-emitting layer EL may include an organic material that emits red, green, and blue light. However, the disclosure is not limited thereto.

The upper electrode CE may be disposed on the light-emitting layer EL, where the upper electrode CE may be a plate electrode. The upper electrode CE may include a metal, an alloy, a conductive metal nitride, a conductive metal oxide, a transparent conductive material, or the like. These may be used alone or in combination with each other. For example, in an embodiment, the upper electrode CE may operate as a cathode.

On the other hand, auxiliary layers may be further formed above and below the organic light-emitting layer EL. The auxiliary layer may be a layer to increase luminous efficiency of the organic light-emitting layer EL. For example, the auxiliary layer may include an electron injection layer, an electron transport layer, a hole injection layer, and a hole transport layer. For example, in case that holes injected from the lower electrode PE and electrons injected from the upper electrode CE meet in the light-emitting layer, the color-light may be emitted.

Accordingly, the light-emitting device LE including the lower electrode PE, the light-emitting layer EL, and the upper electrode CE may be disposed on the base substrate BSUB. The light-emitting device LE may be electrically connected to the transistor TR.

The encapsulation layer TFE may be disposed on the upper electrode CE. The encapsulation layer TFE may protect the light-emitting device LE from external oxygen, moisture, or the like. In other words, in an embodiment, the light-emitting device LE may be disposed between the base substrate BSUB and the encapsulation layer TFE, and the light-emitting device LE may protect by the encapsulation layer TFE from external oxygen, moisture, or the like.

In an embodiment, the encapsulation layer TFE may include at least one inorganic layer and at least one organic layer. For example, the encapsulation layer TFE may have a structure in which inorganic layers and organic layers are alternately stacked.

The encapsulation layer TFE may include a first encapsulation layer (for example, the first inorganic encapsulation layer IL1), a second encapsulation layer (for example, an organic layer OL disposed on the first inorganic encapsulation layer IL1), and a third encapsulation layer (for example, a second inorganic encapsulation layer IL2 disposed on the organic layer OL).

The first inorganic encapsulation layer IL1 and the second inorganic encapsulation layer IL2 may include an inorganic material such as silicon oxide, silicon nitride, silicon oxynitride, or the like. These may be used alone or in combination with each other.

The organic layer OL may include an organic material such as an acrylic resin, a polyimide resin, an epoxy resin, or the like. These may be used alone or in combination with each other. The organic layer OL may fill a defect of the first inorganic layer, or may be formed to flatten an upper surface. In addition, the light-emitting property of the organic light-emitting layer EL may be greater preserved as a moisture permeation path (for example, a path through which the air, the moisture, or the like. penetrates into the organic light-emitting layer) becomes longer.

In an embodiment, the first inorganic encapsulation layer IL1, the organic encapsulation layer OL, and the second inorganic encapsulation layer IL2 may be formed by using the third processing system 300 included in the substrate processing device 1 of FIG. 1.

In the above, it has been described that the inorganic encapsulation layer (for example, the first inorganic encapsulation layer IL1) may be formed on the organic light-emitting layer EL, and the organic encapsulation layer OL may be formed on the inorganic encapsulation layer, however, the disclosure is not limited thereto. For example, the organic encapsulation layer OL may be formed on the organic light-emitting layer EL.

As the substrate SUB on which the upper electrode CE is formed passes through the third processing system 300 included in the substrate processing device 1 of FIG. 1, the first inorganic encapsulation layer IL1, the organic encapsulation layer OL, and the second inorganic encapsulation layer IL2 may be formed sequentially.

FIGS. 6, 7, and 8 are views illustrating the blower included in the substrate processing device of FIG. 1.

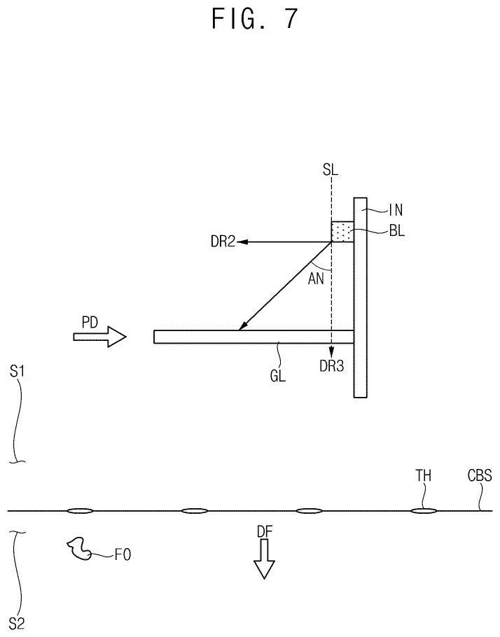

Referring to FIGS. 6 and 7, to maximize the effect of removing the foreign material FO from the substrate GL, a blowing angle and blowing pressure (i.e., pressure of the air) provided by the blower BL may be adjusted. Here, the substrate GL may correspond to the object OB of FIGS. 2, 3, and 4.

In an embodiment, the air may be clean-dry-air (“CDA”). For example, because the fourth processing system 400 of FIG. 1 is under the room pressure condition, the air may include the clean-dry-air to prevent a risk of suffocation. However, the disclosure is not limited thereto. For example, the air may be various gases such as nitrogen.

In an embodiment, the air may be blown obliquely in an opposite direction in which direction the substrate (i.e., the substrate GL) proceeds (i.e., the processing direction PD). In an embodiment, the air may be blown at an angle of about 30 degrees or more and about 50 degrees or less with a virtual normal line SL of the substrate.

In a case that the substrate GL moves to the right, the air may be blown obliquely (to the left) between the second direction DR2 and the third direction DR3. The second direction DR2 may be perpendicular to the virtual normal line SL of the substrate and may be opposite to the direction in which the substrate GL moves (i.e., the direction in which the substrate GL may be moved by the transfer mechanism TR2). The third direction DR3 may be parallel to the virtual normal line SL of the substrate and may be in the gravity direction.

The air-blowing angle may be defined as the angle from the virtual normal line SL of the substrate to the air blown between the second direction DR2 and the third direction DR3. For example, in case that the air is provided in the second direction DR2, the air-blowing angle may be defined as about 0 degrees and in case that the air is provided in the third direction DR3, the air-blowing angle may be defined as about 90 degrees.

If the air-blowing angle is less than about 30 degrees or more than about 50 degrees, speed uniformity provided to an entire surface of the substrate GL may be reduced. For example, excessive air may be provided to some areas of the substrate GL, and the air might not be provided to other areas. Accordingly, the effectiveness of removing the foreign material FO may be reduced.

The air-blowing angle may be about 40 degrees. In this case, by uniformly providing the air to the entire surface of the substrate GL, the effectiveness of removing the foreign material FO may be enhanced.

However, the disclosure is not limited thereto. For example, the air may be blown at the angle ranging from about 0 degrees to about 90 degrees with the virtual normal line SL of the substrate depending on other process conditions.

In an embodiment, an air-blowing pressure may be about 0.2 MPa or more and about 0.4 MPa or less.

In a case that the air-blowing pressure of the air is less than about 0.2 MPa, stagnant air flow stagnates at a bottom of the transfer mechanism TR2, making it difficult to form a downflow DF. In addition, the air might not be provided to an end of the substrate GL. Accordingly, the effectiveness of removing foreign material FO may be reduced.

On the other hand, in case that the air-blowing pressure exceeds about 0.4 MPa, a vortex may be generated at the bottom of the transfer mechanism TR2, thereby increasing a flying distance of the foreign material FO. Scattered foreign material FO may reattach to the substrate GL and cause contamination. Accordingly, the effectiveness of removing foreign material FO may be reduced.

The air-blowing pressure may be about 0.25 MPa. In this case, the lower stagnant airflow and the vortex do not occur, and the foreign material FO is removed along the downflow DF, thereby the effectiveness of removing foreign material FO may be enhanced.

As described above, the blower BL may be located in the pressure fluctuation section. In an embodiment, in case that the substrate processing device (for example, the substrate processing device 1 of FIG. 1) includes a plurality of inspection devices (for example, the first inspection device IN1 and the second inspection device IN2 of FIG. 2), the blower BL may be located at the inlet IN of the standby zone SZ where the substrate GL waits before being input to the plurality of inspection devices. The substrate GL may be transferred from the fourth processing system 400 to the fifth processing system 500 through the inlet IN. Because the blower BL is disposed at the inlet IN, only one blower BL may be installed even if the inspection devices are a plurality.

In an embodiment, the downflow DF may be formed in the second chamber. In an embodiment, a plurality of holes TH may be defined on a bottom surface CBS of the second chamber, and foreign material (i.e., the foreign material FO) removed from the substrate (i.e., the substrate GL) by the air and passing through the plurality of holes TH may be isolated from an internal space S1 of the second chamber.

Based on a bottom surface BS of the second chamber, the foreign material isolation space S2 may be located in the third direction DR3, and the internal space S1 of the second chamber may be located in the opposite direction to the third direction DR3. The internal space S1 and the isolation space S2 may be spatially spaced apart from each other.

Negative pressure may be applied to the second chamber. Accordingly, the foreign material FO trapped in the isolation space S2 might not return to the internal space S1 of the second chamber. Accordingly, the contamination of the substrate GL due to the scattering of foreign material FO may be prevented.

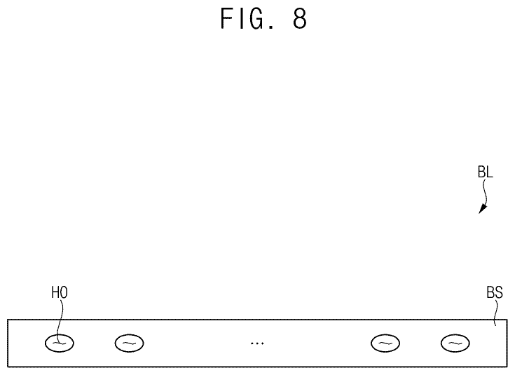

Referring to FIG. 8, the blower BL may have a shape in which the plurality of holes HO is defined in the bottom surface BS. A diameter, number, gap, or the like of the plurality of holes HO may be changed in various ways.

Each of the plurality of holes HO of the blower BL may further include a flow rate controller. Accordingly, the air-blowing pressure provided from each of the plurality of holes HO may be individually controlled.

As a result of applying the substrate processing device (for example, the substrate processing device 1 of FIG. 1) according to an embodiment, a kill ratio determined as a defective substrate GL is reduced by about 15%. The yield may be enhanced as the blower BL blows and removes the foreign material, and the reliability of the display device may be further improved by performing a subsequent process after removing the foreign material.

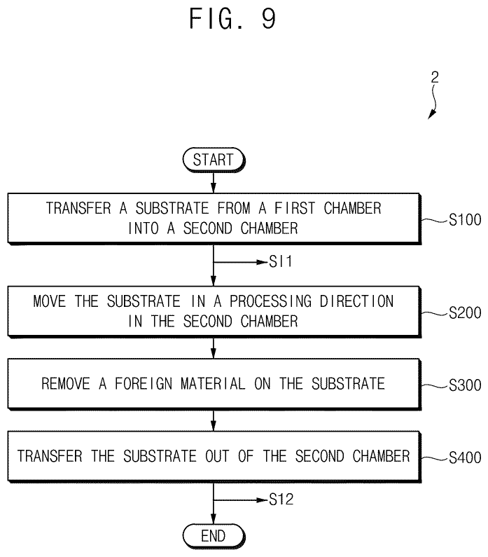

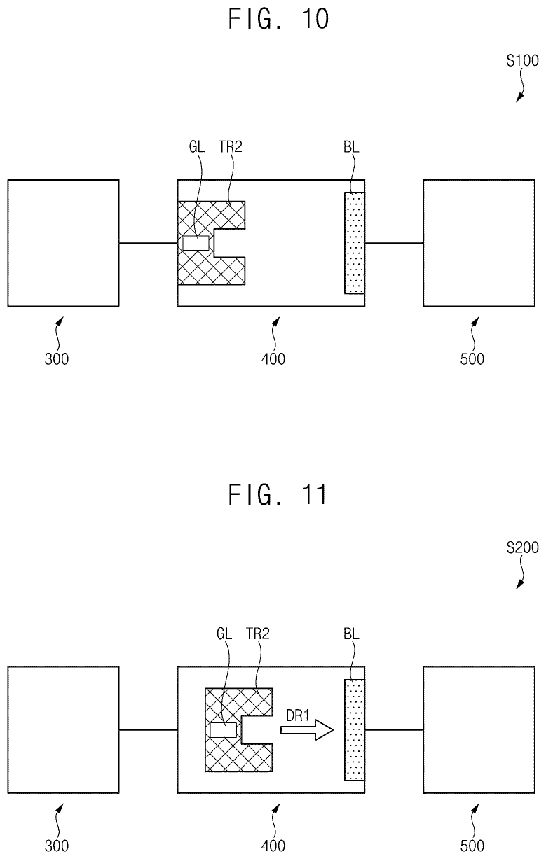

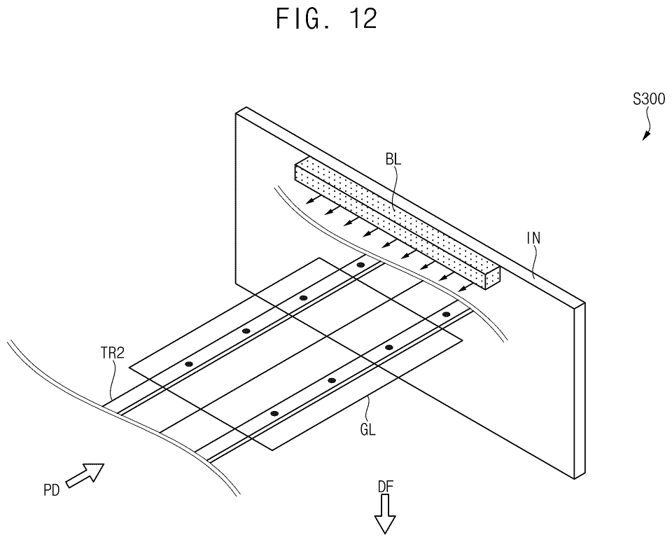

FIG. 9 is a block diagram of an embodiment of a method of processing a substrate. FIGS. 10, 11, 12, and 13 are views illustrating a method of processing a substrate according to an embodiment.

Hereinafter, any repetitive detailed descriptions of the same or like components as those of the device processing device 1 described above with reference to FIGS. 1, 2, 3, 4, 5, 6, 7, and 8 will be omitted or simplified.

Referring to FIGS. 1, 2, 3, 4, 5, 6, 7, 8, and 9, the method of processing a substrate 2 according to an embodiment may include transferring the substrate (for example, the object OB of FIGS. 2, 3, and 4, the substrate GL of FIGS. 6 and 7) from the first chamber (for example, the first chamber included in the third processing system 300) having the first internal pressure into the second chamber (for example, the second chamber included in the fourth processing system 400) having the second internal pressure greater than the first internal pressure (S100), moving the substrate in the processing direction PD in the second chamber (S200), removing the foreign material (for example, the foreign material FO) from the substrate by blowing air on the substrate (S300), and inspecting a presence or absence of the foreign material on the substrate, removing the foreign material from the substrate by blowing the air on the substrate, after transferring the substrate out of the second chamber (S400).

Referring to FIGS. 9 and 10, the substrate GL may be transferred into the second chamber (for example, the second chamber included in the fourth processing system 400) having the second internal pressure carried from the first chamber (for example, the first chamber included in the third processing system 300) having the first internal pressure (S100).

As described above, the second internal pressure may be greater than the first internal pressure. For example, the first internal pressure may be the vacuum, and the second internal pressure may be the room pressure. Accordingly, the foreign material may be attached to the substrate GL.

In an embodiment, the chemical vapor deposition process may be performed in the first chamber. Accordingly, the encapsulation layer included in the substrate GL may be formed (encapsulation process).

After the encapsulation process is completed, the substrate GL may be carried out from the third processing system 300. The carried out substrate GL may be transferred into the fourth processing system 400 and the oven process may be performed.

As described above, after forming the transistor TR, the primary cleaning may be performed before being input into the third process unit 300 to form the light-emitting element LE. Through the primary cleaning, the foreign material on the substrate GL may be primarily removed before forming the light-emitting device LE.

In a case of the substrate processing method according to the comparative embodiment, secondary cleaning does not proceed when the substrate is transferred from the third processing system 300 to the fourth processing system 400 (that is, in the pressure fluctuation section). As the vacuum condition changes to the room pressure condition, the foreign material, or the like may attach to the substrate GL, causing contamination. In case that the subsequent process proceeds without removing the foreign material, subsequent layers may be formed on the foreign material. The foreign material buried within the subsequent layers may appear as the defect such as the dark spot on the display device. Accordingly, the reliability of the display device may be lowered.

However, in the case of the method of processing a substrate 2, the foreign material may be removed by the blower BL. Accordingly, the occurrence of the above-mentioned contamination may be prevented. In addition, the reliability of the display device can be enhanced.

Referring to FIGS. 9, 10, and 11, the substrate may be transferred in the processing direction (e.g., the first direction DR1) in the second chamber (e.g., the second chamber included in the fourth processing system 400) (S200).

The substrate GL may be moved in the second chamber by the transfer mechanism TR2. At this time, the air may blow from the blower BL just before the substrate GL is transferred into the second chamber, and the air may be continuously blown from the blower BL while the substrate GL moves through the second chamber. However, the disclosure is not limited thereto. For example, the air may be blown from the blower BL immediately after the substrate GL is transferred.

Referring to FIGS. 7, 9, and 12, the foreign material (for example, the foreign material FO) on the substrate GL may be removed (S300).

In an embodiment, the foreign material may be removed by blowing the air on the substrate GL. In an embodiment, the air may be blown obliquely in the opposite direction to the processing direction PD. In an embodiment, the air may be blown at the angle of about 30 degrees or more and about 50 degrees or less with the virtual normal line SL of the substrate GL. In addition, in an embodiment, the air may be blown at the pressure of about 0.2 MPa or more and about 0.4 MPa or less. Accordingly, the foreign material FO on the substrate GL may be effectively removed. However, the disclosure is not limited thereto. The air-blowing angle, the air-blowing pressure, or the like may be changed in various ways.

In an embodiment, the air may be clean-dry-air (“CDA”). However, the disclosure is not limited thereto. A type of the air may be changed in various ways.

In an embodiment, the downflow DF may be formed in the second chamber. In an embodiment, the foreign material FO removed from the substrate GL by the air may pass through the plurality of holes TH defined on the bottom surface CBS of the second chamber and may be isolated from the internal space S1 of the second chamber. Accordingly, the contamination of the substrate GL due to the re-scattering of foreign material FO may be prevented.

In an embodiment, a first signal SI1 may be generated when the substrate GL is carried out from the third processing system 300 (e.g., the first chamber included in the third processing system 300). In response to the first signal SI1, the air may begin to be blown from the blower BL.

In an embodiment, the air may continue to be blown on the substrate GL while the substrate GL passes through the inlet IN from the fourth processing system 400 to the fifth processing system 500. Accordingly, the attachment of the foreign material due to the movement of the substrate GL may be prevented.

In an embodiment, the air-blowing may be stopped after the selectable time has elapsed. In an embodiment, the air may be blown until the substrate GL is carried out from the fourth processing system 400 and completely transferred into the fifth processing system 500. For example, when the substrate GL waits in the fourth processing system 400 for about 3 seconds, the air-blowing may stop after about 7 seconds. However, the disclosure is exemplary, and an air-blowing time may be changed in various ways. In addition, as another example, the air may generate a second signal S12 when the substrate GL is carried out from the fourth processing system 400. In response to the second signal S12, the air may stop being blown from the blower BL.

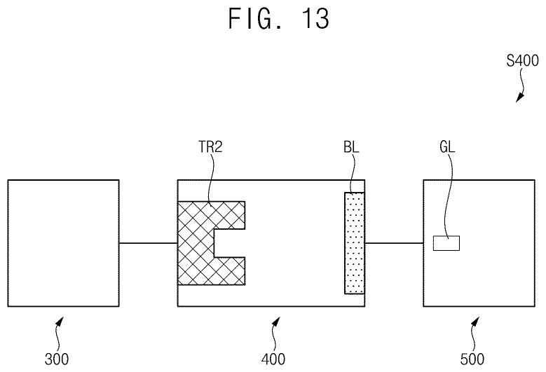

Referring to FIGS. 9 and 13, the substrate GL may be carried out from the fourth processing system 400 (S400).

As described above, the substrate GL may be transferred into the empty inspection device (for example, any one of the first inspection device IN1 or the second inspection device IN2 of FIG. 2) after the substrate GL stands by in the standby zone SZ, in the fifth processing system 500. The presence or absence of the foreign material on the substrate GL may be inspected using the inspection device.

By primarily removing the foreign material from the substrate GL using the blower BL before entering the inspection machine, the kill ratio of the substrate GL in the inspection device may be further reduced (That is, the defect caused by the foreign material may be reduced and the yield may be enhanced). In addition, by removing the foreign material from the substrate GL using the blower BL, the defect caused by the foreign material may be prevented (that is, the reliability of the display device may be further enhanced).

An object OB produced by the substrate processing line according to embodiments may be applied to a computer, a notebook, a cell phone, a smart phone, a smart pad, a PMP, a PDA, a MP3 player, or the like.

Although the display device and the method of manufacturing the same according to the embodiments have been described with reference to the drawings, the illustrated embodiments are examples, and may be modified and changed by a person having ordinary knowledge in the relevant technical field without departing from the technical spirit described in the following claims.

What is claimed is:

1. A substrate processing apparatus comprising:
a first chamber having a first internal pressure;
a second chamber connected to the first chamber and having a second internal pressure greater than the first internal pressure;
a transfer mechanism located in the second chamber and configured to move a substrate in a processing direction; and
a blower located in the second chamber and configured to blow air onto the substrate.

2. The substrate processing apparatus of claim 1, wherein in operation the air is blown obliquely in a second and third direction in which the second direction is opposite to the processing direction.

3. The substrate processing apparatus of claim 2, wherein in operation the air is blown at an angle of about 30 degrees or more and about 50 degrees or less with a virtual normal line of the substrate.

4. The substrate processing apparatus of claim 1, wherein an air blowing pressure is about 0.2 MPa or more and about 0.4 MPa or less.

5. The substrate processing apparatus of claim 1, wherein in operation a downflow is formed in the second chamber.

6. The substrate processing apparatus of claim 1, wherein,
a plurality of holes is defined in a bottom surface of the second chamber, and
in operation a foreign material is removed from the substrate by the air, passes through the plurality of holes, and is isolated from an internal space of the second chamber.

7. The substrate processing apparatus of claim 1, wherein the air is clean-dry-air.

8. The substrate processing apparatus of claim 1, further comprising:
a third chamber connected to the second chamber and in which a foreign material detector is located inside.

9. The substrate processing apparatus of claim 8, wherein the foreign material detector is a plurality of foreign material detectors.

10. The substrate processing apparatus of claim 1, wherein the first chamber is a chemical vapor deposition chamber.

11. A method of processing a substrate comprising:
transferring a substrate from a first chamber having a first internal pressure into a second chamber having a second internal pressure greater than the first internal pressure;
moving the substrate in a processing direction in the second chamber; and
removing a foreign material from the substrate by blowing air on the substrate.

12. The method of processing a substrate of claim 11, wherein the air is blown obliquely in a second and third direction in which the second direction is opposite to the processing direction.

13. The method of processing a substrate of claim 12, wherein the air is blown at an angle of about 30 degrees or more and about 50 degrees or less with a virtual normal line of the substrate.

14. The method of processing a substrate of claim 11, wherein an air blowing pressure is about 0.2 MPa or more and about 0.4 MPa or less.

15. The method of processing a substrate of claim 11, wherein a downflow is formed in the second chamber.

16. The method of processing a substrate of claim 11, a foreign material is removed from the substrate by the air, passes through a plurality of holes defined in a bottom surface of the second chamber, and is isolated from an internal space of the second chamber.

17. The method of processing a substrate of claim 11, wherein the air is clean-dry-air.

18. The method of processing a substrate of claim 11, further comprising:
inspecting for a presence or absence of the foreign material remaining on the substrate after removing the foreign material from the substrate by blowing the air on the substrate.

19. The method of processing a substrate of claim 11, wherein,
a first signal is generated when the substrate is carried out of the first chamber,
the air begins to be blown in response to the first signal, and
the blowing of the air is stopped after a selected time has elapsed.

20. The method of processing a substrate of claim 19, wherein a chemical vapor deposition process is performed in the first chamber.
